(19) United States
(12) Patent Application Publication
(10) Pub. No.: US 2005/0244013 A1
(43) Pub. Date: Nov. 3, 2005

(54) Noise exposure monitoring device

(75) Inventors: Philip J. Battenberg, Oconomowoc, WI (US); Cliff D. Wolcott JR., Hartland, WI (US); William J. Nielsen, Watertown, WI (US); Patrick J. Kilps, Hubertus, WI (US)

Correspondence Address: MICHAEL BEST & FRIEDRICH, LLP, 100 E WISCONSIN AVENUE, MILWAUKEE, WI, 53202, US

(73) Assignee: Quest Technologies, Oconomowoc, WI (US)

(21) Appl. No.: 10/834,604

(22) Filed: Apr. 29, 2004

(51) Int. Cl. H03G 3/20

(52) U.S. Cl. 381/57; 381/56; 381/94.1

(57) ABSTRACT

A noise monitoring device for indicating exposure to noise and providing a quickly perceived noise exposure warning. Noise levels are monitored, recorded and evaluated by the device utilizing a noise detector, an accumulator, and an evaluator that monitors an accumulated noise signal value and determines a probability that continued exposure to the noise will exceed an acceptable value and issues a noise exposure warning if that probability exceeds a predetermined value. The noise exposure warning comprises a quickly perceived indicator such as a readily perceived visual symbol or tactile warning.

### TECHNICAL FIELD OF THE INVENTION

This invention relates to noise exposure monitoring devices, and in particular to a noise exposure monitoring device for continuously and accurately monitoring an individual's noise exposure, evaluating that exposure, and issuing a warning to the individual that acceptable levels are exceeded or will be exceeded if noise exposure continues.

### BACKGROUND OF THE INVENTION

In a work environment, the accumulated amount of noise, or dose in terms of an average noise level, and the maximum level of noise to which an individual has been exposed during a workday are important to occupational safety and to the health of the individual.

Many organizations have studied the detrimental effect of high sound levels on hearing. As a result, standards have been developed to insure hearing safety. In the United States, the Occupational Safety and Health Administration (“OSHA”), the Mine Safety and Health Administration (“MSHA”), and the American Conference of Governmental Industrial Hygienists (“ACGIH”) have all set limits on how much environmental noise is permissible. These limits are commonly cited in workplace standards and in the engineering of noise measurement or monitoring devices.

Examples of such noise data measurements include impulse noise, continuous noise, and an eight-hour time-weighted average (“TWA”). Impulse noise relates to noise of very short duration, less than a few thousandths of a second, which also repeats less than once a second. Continuous noise relates to noise that is longer in duration than impact noise, extending over seconds, minutes, or hours, Eight-hour TWA relates to the average of all levels of impulse and continuous noise to which an employee is exposed during an eight-hour workday. The OSHA maximum level for impulse noise is 140 dBSPL measured with a fast peak-hold sound level meter (“dBSPL” stands for sound pressure level, or a magnitude of pressure disturbance in air, measured in decibels, a logarithmic scale). The maximum level for continuous noise is 115 dBA. OSHA regulations limit an eight-hour TWA to 90 dBA. If employees are exposed to eight-hour TWAs between 85 and 90 dBA, OSHA requires employers to initiate a hearing conservation program which includes annual hearing tests.

The U.S. Department of Labor Occupational Noise Exposure Standard (29 C.F.R. §1910.95) specifies that noise dosimetry may be used to measure noise exposure on individuals in the workplace. The standard requires that individuals exposed to greater than 85 dBA TWA must be included in a Hearing Conservation Program. The allowable exposure to noise is measured in terms of cumulative noise dose, which means individuals are considered to be within compliance if they are exposed to less than 90 dBA TWA (a 100% dose) over an eight hour workday. Total noise dose during the work day is calculated as D=100 (C₁/T₁+C₂/T₂+ . . . . Cₙ/Tₙ), where D is percentage noise dose, C is total length of the specific exposure, in hours, and T is reference duration corresponding to the measured sound level (See 29 C.F.R. §1910.95, Table G-16A, 1999). A TWA of the A-weighted sound level may be calculated from the dose measurement by means of the formula, TWA=16.61 log₁₀ (D/100)+90. This provides a mechanism for accumulating exposures of varying levels and durations where an “exchange rate” of the dBA for four hours is considered equivalent to either 1) an exposure of 85 dBA for eight hours or 2) an exposure of 95 dBA for two hours. Noise dosimeters are employed to measure cumulative noise dose by applying the “exchange rate” to the level and duration of exposure.

Noise dosimetry is commonly used in industry, and noise dosimetry measurements are used to indicate cumulative exposure to noise over a full work shift. In addition to determining which employees should be included in the Hearing Conservation Program, noise measurements are commonly used to determine hearing protector requirements, and to assess noise control requirements. Information gathered by noise dosimeters is typically used by occupational health and safety practitioners, and is not intended for interpretation by the worker. In fact, in many situations, readouts of dosimeters are sealed shut so that the wearer has no visible indication of current exposure or dose.

In order to prevent hearing loss without having to leave the area, Hearing Protective Devices (“HPD”) such as earmuffs, ear plugs, and semi-aural devices, are used to provide attenuation in the workplace. These protective devices can be very effective for preventing hearing loss. However, most workers are reluctant to wear Hearing Protective Devices all day and prefer to use protective devices only when necessary. While measuring the actual noise in the environment of the workplace is important, it is very helpful to the user of the noise dosimeter if the user is issued a warning in time to begin using appropriate hearing protection devices or otherwise reduce noise exposure, to prevent risk of hearing damage.

Today, workers in the United States continue to experience a high incidence of Noise Induced Hearing Loss (“NIHL”) despite the existence of federal legislation designed to prevent such injuries. Much of the current state of hearing conservation can be attributed directly to the reliance, over the last 30 years, on limited or single-shift noise exposure data and personal hearing protection as the first, and only, line of defense against hazardous noise. Past efforts to protect workers from occupational noise have focused primarily on achieving compliance with the noise regulations and detecting hearing loss, rather than prevention. Often the worker becomes aware of the need for protective measures at a point beyond the critical level of noise exposure causing unnecessary risk of over exposure. Thus, a new solution is needed to facilitate upstream prevention of noise induced hearing loss.

Consequently, there is a need for a device that provides a means of monitoring an individual's noise exposure and providing a warning to that individual early enough to permit the individual to take appropriate measures to protect their hearing.

### SUMMARY OF THE INVENTION

An important and unique aspect of the current invention is that the device is designed to monitor and analyze noise in a manner such that the user or worker receives a warning of impending undesirable noise exposure early enough to take appropriate protection measures. The current invention provides a device and system allowing accurate measurement of noise exposure over the course of the entire workday and for providing a symbolic visual display warning to the user early enough to prevent undesirable noise exposure.

One feature of the current invention is an Alert Level warning. The Alert Level warning, visual, tactile, or in some other form, indicates when the noise monitoring device user has been exposed to a cumulative dose that is equal to an action level. Action level is a level at which noise-induced hearing damage may occur. Exposures below the action level are, in general, considered to be safe. Remedial measures should take place before an action level is attained.

In a preferred embodiment, a tactile warning indicator which includes a vibrator circuit responsive to a high noise condition, functions as an Alert Level warning indicator. In a preferred embodiment, the vibrator circuit comprises a belt clip mounted vibrator that vibrates when a preset noise level or dose level is exceeded. These vibrations may be repeated at various intervals to ensure that the warning is effectively delivered to the wearer.

It is also a feature of the present invention is to provide a noise monitoring device for indicating exposure to noise wherein the device evaluates accumulated noise over a period of time and determines a probability that continued exposure to the detected noise will exceed an acceptable value and issues a noise exposure warning if the projected time-weighted average of the noise exceeds a pre-determined Alert Level.

Other important objects, features, and advantages of the invention will be apparent to the reader from the foregoing and the appended claims and as the ensuing detailed description and discussion of the invention is read in conjunction with the accompanying drawings.

### BRIEF DESCRIPTION OF THE VARIOUS VIEWS OF THE DRAWINGS

In the drawings, like reference numerals refer to like parts throughout the various views, unless otherwise indicated, and wherein:

FIG. 1 is an isometric view of an embodiment of the noise monitoring and warning device of the present invention;

FIG. 2 is a block diagram representing noise dosimetry hardware located inside the noise monitoring and warning device shown in FIG. 1;

FIG. 3 is an isometric view of the present invention including two alternate embodiments of belt clips used with the noise monitoring and warning device in FIG. 1;

FIG. 4 is a front view of a user panel of the noise monitoring and warning device in FIG. 1; and

FIG. 5 is a liquid crystal display forming a portion of the user panel shown in FIG. 4.

### DETAILED DESCRIPTION OF THE INVENTION

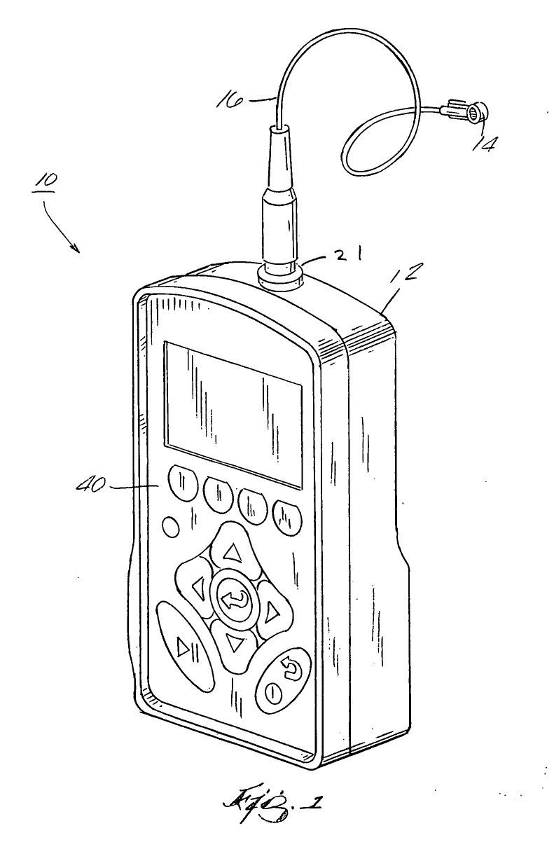

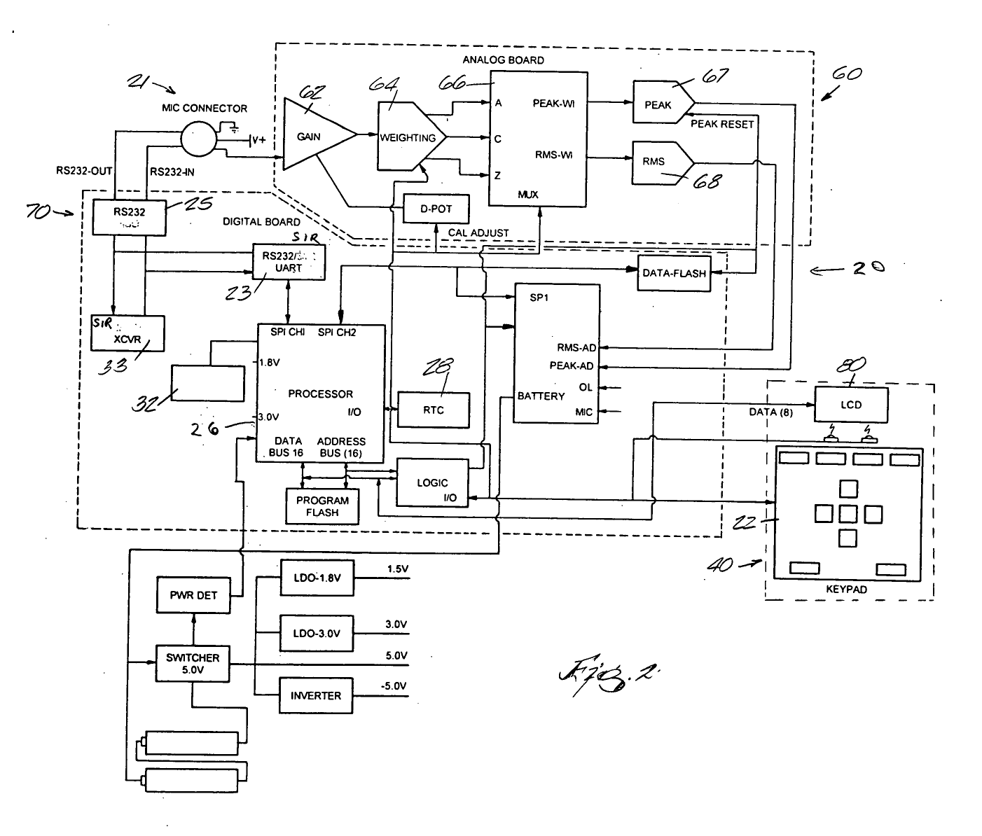

Referring now to the drawings, FIG. 1 illustrates a preferred embodiment of the continuous noise monitoring and warning device shown at 10. The noise monitoring device 10 in FIG. 1 is a noise dosimeter that can provide comprehensive information under varying conditions, in multiple locations with a variety of user settings. This noise dosimeter is typically used or worn by a user in a work environment. In the embodiment shown, an outer case 12 is provided with user controls, visual display, and contains noise dosimetry hardware, (illustrated generally in block diagram in FIG. 2).

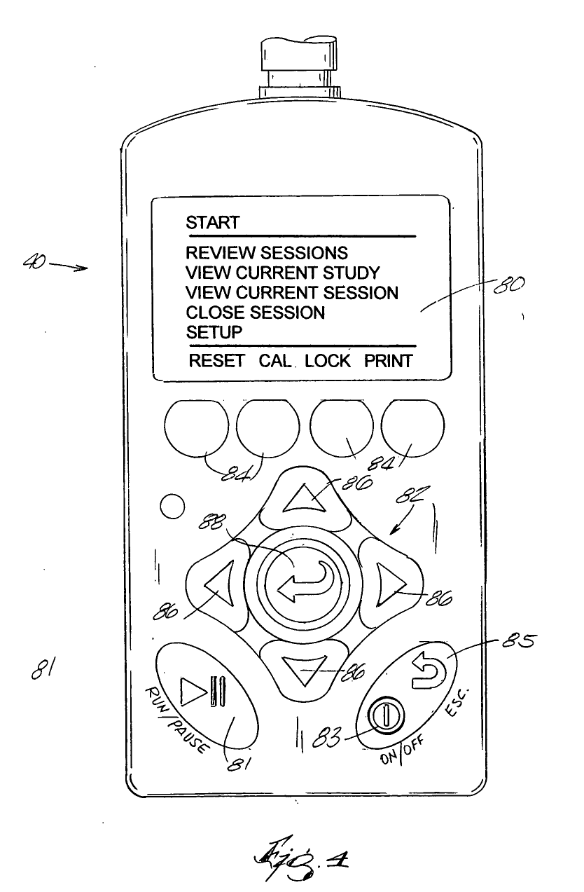

Noise dosimetry is the process of measuring sound and protecting hearing. To do this well, a noise monitoring device or dosimeter must provide comprehensive information under varying conditions, in multiple locations and with a variety of user settings. A noise dosimeter should also be easy to use. To enable easy use, a user panel 40 is provided on the front of the case 12 in a location and size that permits easy and convenient viewing and use by the operator of the noise monitoring device. A more detailed illustration of the user panel 40 is shown in FIG. 4. A detailed description of the functions and use of the user panel 40 will be presented later in this description.

Referring again to FIG. 1, a microphone, such as the microphone shown at 14, is used to measure sound level. The external microphone shown at 14 can be used in a variety of locations. Generally, the microphone is clipped to an item of clothing to keep the microphone in a general vicinity of the user's hearing zone. One very useable location is a shoulder-mounted position. The microphone 14 is connected to the outer case 12 by an electric cable 16. The microphone 14 provides an electrical signal that is proportional to detected noise level. The electrical signal from the microphone is transferred within the case 12 to noise dosimetry hardware 20 (not shown in FIG. 1 but shown in block diagram in FIG. 2).

While a remotely-mounted microphone is shown in FIG. 1, it is also very useful and convenient to perform area noise monitoring with the use of a boom-mounted microphone (not shown). Generally when a boom-microphone is used, the noise monitoring device is left at a single location to monitor the noise in the general area of a work environment. Various other types of microphones or the like may be used depending on what type of noise measurement is desired.

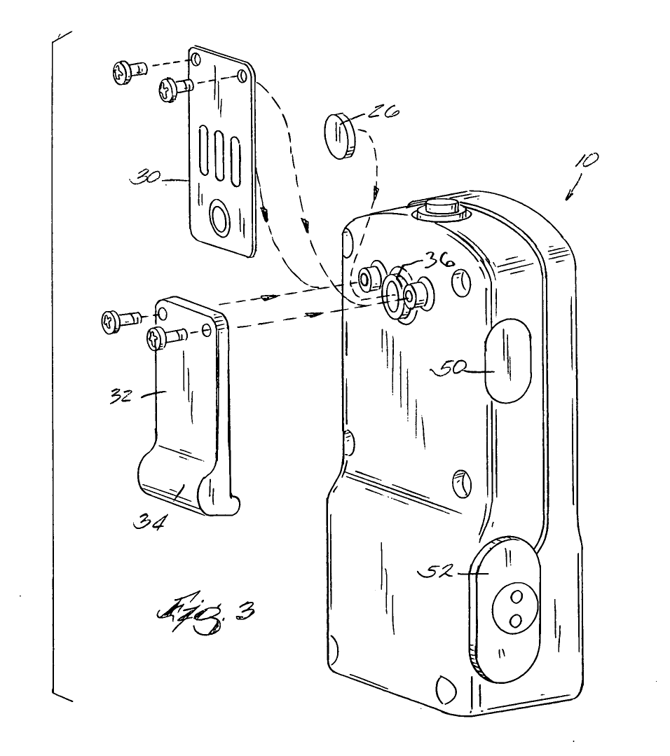

Referring now to FIG. 2, the block diagram representing noise dosimetry hardware 20 is shown. The hardware, in combination with software within a central processor 26, provides an accumulator function and an evaluator function. The accumulator function accumulates the electrical signal provided by the microphone. The evaluator function continuously monitors and evaluates the signal representative of accumulated noise as stored in the accumulator. The central processor 26 provides these functions and continuously monitors calculated results. The central processor 26 also receives signals provided by the user through a keypad 42. In turn, the central processor 26 transmits information to a liquid crystal display 80 for viewing by the user of the noise monitoring device. Additionally, the central processor can transmit information to external devices (not shown) via an infrared transmitter 33 in FIG. 2 and generally shown at 50 in FIG. 3.

Referring again to FIG. 2, the functions performed by the hardware start with receipt of the signal from the microphone. The noise level is detected by the microphone 14 and transmitted as an electrical signal via cable 16 into the noise monitoring device through a microphone connector 21. At this point the noise is represented by an analog electrical signal. This electrical signal must be evaluated. To accomplish this, the gain and level are adjusted and weighted as appropriate for the noise monitoring device. This is accomplished on an analog board 60 that comprises appropriate analog components. The signal from the microphone connector 21 enters the analog board at a gain component 62. The resultant electrical signal is then sent to a weighting component 64. The weighting component 64 divides the signal into an A signal, a C signal, and a Z signal, all of which are transferred to a Multiplexer (MUX) component 66. The MUX component 66 separates the three signals and transmits a peak signal to a peak component 67 and a noise level signal to an RMS detector 68. The peak component 67 and RMS detector 68 convert each of these signals respectively from analog to digital form with an analog to digital converter. Peak levels and overload are sampled and converted from analog to digital as well. The digital signal levels are accumulated by the central processor 26 which saves the values and evaluates if any alarm limits have been reached.

Components on a digital board 70 process the noise signals in digital form primarily using the central processor 26 as well as other components. The digital levels are accumulated by the processor 26 which saves the values and compares them to the user set alarm limits. If the alarm limit has been exceeded, the processor 26 sends a signal in the form of a easily recognized, visible symbol or a digital value or a tactile warning or any combination thereof that is appropriate or as determined by user settings. The processor 26 sends a signal with data to a Liquid Crystal Display (LCD) 80 if the warning is in the form of a digital or a visual symbol. It is preferred that any warning signal be easily recognizable. If the warning is to be provided in a tactile form, the processor 26 sends a signal to a vibrating device 34 which may, in one embodiment, be mounted on a belt clip 32 (as shown in FIG. 3). While performing these and other operations, the processor 26 also keeps track of time values which are obtained from a real-time clock 28.

Referring now to FIG. 3, the noise monitoring device 10 is shown with two alternative forms of belt clips. A standard belt clip 30 is shown for attaching the noise monitoring device 10 to a belt or similar item of clothing. Additionally, a vibrating belt clip 32 is shown with a vibrating device 34. A vibrating belt clip is used in situations where it is desirable to provide a tactile or vibrating warning to the user of the noise monitoring device 10. When a vibrating belt clip 32 is used it is connected to the noise monitoring device with a power connector 36 for providing electrical power to the vibrating belt clip 32.

Also shown on FIG. 3 on the outside of the noise monitoring device 10 is the infrared transmitter 50 and a battery compartment cap 52. The noise monitoring device 10 as shown in this embodiment is powered by batteries. These batteries are installed into a battery compartment by opening the battery cap 52. Various other forms of power supply might be used in addition to batteries.

While the noise monitoring device can function solely on its own, it is also capable of communicating with printers or personal computers or the like. The processor 26 sends setups and data to and from external sources through a Universal Asynchronous Receiver Transmitter (UART) (in this case, an RS 232/SIR UART) which converts the data into an infrared serial data signal and sends it through the serial infrared data transmitter 33 shown in FIG. 2 to an external device (not shown).

Referring now to FIG. 4, the user panel 40 is shown including the liquid crystal display 80 and user controls generally shown at 82. The user controls include soft keys 84, up/down left/right selectors 86, enter button 88, start/stop studies 81, on/off button 83 and escape button 85.

The on/off button 83 powers the noise monitoring device 10 on and off. The escape button 85 denotes the keys escape function (backing up to a previous display) that can be used to move backward along a display path.

In the embodiment shown, the user can customize display characteristics and verify, or change, clock settings before running studies of noise. The selector keys 86 are used to select time, date and display on the liquid crystal display 80. The soft keys 84 are used to select different displays and each soft key is shown directly below the display that it selects.

It is commonly a priority to calibrate the noise monitoring device 10 before initial use. Noise measurements are only as good as the calibration of the measuring instrument. A calibrator is a portable device emitting sound at a fixed frequency and sound level. For some calibrators, the signal frequency and sound level can be selected. Generally, the indicated frequency and sound level is specified on the calibrator. Typically, the noise monitoring device 10 is calibrated using a calibrator in conjunction with the microphone 14. The selectors 86 are used to adjust the value shown on the liquid crystal display 80 so that it is equal to the calibrator's labeled output level.

The noise monitoring device 10 generally comes with default settings but these settings can be changed to suit individual purposes. For example, the user may initially check the time to verify that it matches local time. A setup display is provided on the liquid crystal display 80 which will display date, days of the week and time. The time entered into the noise monitoring device 10 can be changed through the selectors.

If the noise monitoring device 10 is used as a logging dosimeter, the logging rate and logging triggers can be set by the user. The user can individually enable and disable time-history logging. The user can also enable and disable logging for maximum and minimum noise levels and for noise ceiling times.

### Configuring the Noise Monitoring Device

It will now be explained how a user may view and define setup conditions for the noise monitoring device 10.

The performance of a noise dosimeter can be controlled by commonly recognized parameters that regulate how the dosimeter responds to time-varying noise signals. When reporting dosimetry results, the settings of several critical parameters should be reported at the same time so that meaningful comparisons can be made.

The collection of settings to the parameters that control the noise monitoring device 10 is known as dosimeter setup. In one embodiment the noise monitoring device 10 provides nine dosimeter setups, and any of them can be assigned. Some of the setups have fixed settings that cannot change; others allow the user to make changes that conform to individual requirements. When the noise monitoring device 10 is configured, it is assigned one of the nine setups.

In the embodiment shown in FIG. 1, six of the nine dosimeter setups are pre-defined in the factory, and five of the six cannot be changed by the user. The factory assignments conform to standards established for noise dosimetry in the United States and the European Union.

The five that are fixed comply with standards established by the Occupational Health and Safety Administration (“OSHA”), the Mine Safety and Health Administration (“MSHA”) and the American Conference of Governmental Industrial Hygienists (“ACGIH”). The sixth, labeled 200310EC, complies with minimum requirements under Directive 2003/10/EC of the European Union. The settings to the 2003/10/EC parameters can be changed to accommodate preferences for more stringent standards in member EU countries.

In addition to the factory defined setups, the noise monitoring device shown at 10 has three additional setups. Users can change any of the settings in these setups and save the results.

Measurement results in the noise monitoring device 10 and its display 80 can be viewed or reviewed at the user's option. Viewing means looking at the most current measurements. Reviewing means looking at measurements resulting from a complete study or resulting from a previous session. If the user is viewing results while running a study, the results are being acquired and displayed in real-time. If the user is viewing a study during a pause, the final results from the last study performed are displayed.

After the user has customized display characteristics, various items of information will be displayed on the liquid crystal display 80. Data is presented on the liquid crystal display 80 for viewing in a data results display. Various results of data will be displayed depending on what is selected by the user. Typically, the display will include a source type, which means a navigation line that tells whether the display is showing study or session results. Secondly, there is displayed a dosimeter profile. This is the name of a profile assigned to one of a number of active dosimeters which sets the conditions for measurement results. Thirdly, a section of the liquid crystal display 80 will show descriptors. Descriptors are measurements made, separated into level, average and dose categories. For example, a Level category contains an SPL, Peak, Maximum, and Minimum descriptors. Fourthly, run time will be displayed and is typically given in hours, minutes, and seconds. The user can tell if the study is currently running by looking to see if run time is increasing or not. Fifthly, a response is shown which is a parametric setting for a selected dosimeter profile. Sixthly, out-of-range indicators are shown. Normally nothing appears to indicate out-of-range. If the user sees a display in an out-of-range section, this means an out-of-range low or high noise level condition has occurred. Out-of-range indicators tell whether the input signal to the dosimeter is above or below the linear operating range of the dosimeter. If an overload occurs while running a study, the out-of-range indicator appears and stays indicated.

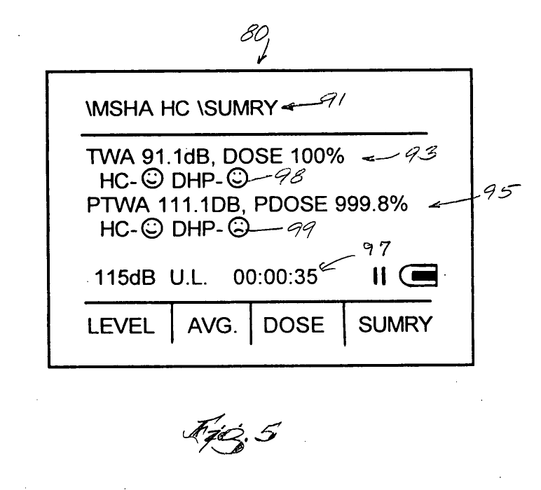

Referring now to FIG. 5, a typical display showing results of a study during use of the noise monitoring device 10 is shown. A first line designated a dosimeter set-up line is indicated at 91. This information is user-selected. After the dosimeter set-up line, various forms of measured sound level and calculated or evaluated information as a result of the detected sound level is displayed. A first measurement in this category reports current sound level. The measurement of current sound level is always displayed in a preferred embodiment, even when a session is closed by the user. In effect, the user can monitor sound level as if the noise monitoring device 10 were a level meter by viewing the measurement of current sound level.

Beyond measurement of current sound level, various interpreted summaries are shown. Direct measurements of TWA and Dose, and calculated measurements of Predicted TWA and Predicted Dose, are repeated and interpreted in a summary display. This display also shows upper limit threshold and time the noise ranged above that threshold.

A typical display by the invention of interpreted summaries is shown in FIG. 5. Direct measurements are shown at 93, projected values are shown at 95, and upper limit values are shown at 97.

One aspect of the present invention is a unique form of displaying actual and interpreted summaries for the user. In the embodiment shown in FIG. 5, both numerical values and readily perceived visual symbols are used to immediately indicate to the user in a very easily understood and readily perceived manner that the user has been exposed to acceptable sound levels or unacceptable sound levels. Specifically, in the embodiment shown, a first or happy face icon 98 is used to indicate to the user that exposure is within acceptable ranges. On the other hand, a different or sad fact icon 99 is used to indicate to the user that a particular noise exposure parameter has or will exceed acceptable levels. Such use of icons has been found to be very helpful to the user to give an immediate and useable indication of acceptable or unacceptable sound levels so that the user can readily perceive an unacceptable noise level measurement and take action very quickly. While numerical values are also displayed, an icon or symbolic display based on calculated information that is compared to levels set by government standards or by the user in a customized fashion, provides a useful, readily, and easily perceived display.

Icons as shown in FIG. 5 in the summary display represent ranges above or below an Alert Level. When a measured or projected time-weighted average is below an Alert Level, a happy face icon (favorable result) is shown. When the measured or projected time-weighted average is equal or above an Alert Level, a sad face icon is shown (unfavorable result). Because Alert Levels are typically set at regulatory compliance levels, these icons represent real-time compliance indicators.

For some pre-defined set-ups, a second Alert Level exists. For user set-ups, the user can set one or two Alert Levels. Again, a happy face icon or sad face icon is used to indicate measurement above or below a pre-defined Alert Level.

The ability of the noise monitoring device 10 to set Alert Levels based on government standards or user defined standards and provide the user with a very quickly perceived warning is a unique and valuable feature of the present invention. Providing the user with a symbolic or icon display or tactile warning to indicate compliance or non-compliance with government-set standards and give a warning to the user before exceeding such standards and potentially incurring hearing loss is a valuable feature of the subject invention.

While happy and sad face icons are used in the embodiment shown, various other readily perceived visual symbols might also be used.

Each compliance icon is tagged to show the purpose of that particular Alert Level. For pre-defined Alert Levels, these tags are for hearing conservation, permissible exposure limits and dual hearing protection. For user-defined Alert Levels, the tags are exclamation points (“!”) with no pre-defined meaning. Users attach their own interpretation to these indicators.

The user can also restrict access to noise dosimeter run and setup controls by means of separate security codes. The user can define these codes. The user can enable, disable, and choose the codes for the security system in a security control display.

It will be apparent to the reader that the invention may be embodied in many forms in addition to those disclosed herein without departing from the spirit of essential characteristics of the invention. The present embodiments are therefore to be considered in all respects as illustrative and not restrictive. The scope of the invention is indicated by the appended claims rather than by the foregoing description and the drawings, and all changes which come within the meaning and range of equivalency of the claims are therefore intended to be embraced therein.

1. A noise monitoring device for indicating exposure to noise and providing a noise exposure warning, comprising:
a noise detector for detecting noise level and for generating a signal having a magnitude proportional to the detected noise level;
an accumulator for accumulating said signal value over a period of time;
an evaluator for monitoring the accumulated signal value and determining a probability that continued exposure to the detected noise will exceed an acceptable value causing said noise monitoring device to issue a noise exposure warning if said probability exceeds a predetermined value; and
said noise exposure warning comprises a quickly perceived indicator.

2. The noise monitoring device of claim 1 wherein said warning is a tactile warning.

3. The noise monitoring device of claim 2 wherein said tactile warning is provided by a belt clip mounted vibrating device.

4. The noise monitoring device of claim 3 wherein said belt clip includes an input connection for accepting an activation signal from the noise monitoring device.

5. The noise monitoring device of claim 1 wherein said warning comprises a visual display comprising readily perceived visual symbols.

6. The noise monitoring device of claim 5 wherein said visual symbols comprise a first icon to indicate noise exposure below a designated Alert Level and a different icon to indicate noise exposure above a designated Alert Level.

7. The noise monitoring device of claim 6 wherein said visual display includes accumulated exposure compliance status and projected exposure compliance status.

8. The noise monitoring device of claim 7 wherein criteria for determining exposure compliance status are user-defined as well as pre-defined.

9. The noise monitoring device of claim 8 wherein said user-defined compliance status is accomplished with a software template.

10. The noise monitoring device of claim 7 having a daily exposure warning and a hearing protection required warning.

11. The noise monitoring device of claim 10 wherein said daily exposure warning and said hearing protection required warning have trip points that are user-defined.

12. The noise monitoring device of claim 5 wherein said visual display includes indicated value of accumulated noise exposure.

13. The noise monitoring device of claim 5 wherein said visual display comprises at least a first smiling face icon indicating acceptable noise exposure and a different sad face icon indicating unacceptable noise exposure.

14. The noise monitoring device of claim 1 wherein said device includes an individual device identification communicator.

15. The noise monitoring device of claim 14 wherein said device is provided with a remote device programming interface and data retrieval interface.

16. The noise monitoring device of claim 15 wherein said remote device programming interface and said data retrieval interface are capable of communicating with a remote device programming and data retrieval instrument.

17. The noise monitoring device of claim 1 having multiple user selectable settings.

18. The noise monitoring device of claim 17 wherein said user selectable settings include: setup display, time response, frequency rating, exchange, criterion level, criterion time, noise threshold, and noise upper limit.

19. The noise monitoring device of claim 18 wherein said device is provided with a remote interface capability to enable said noise monitoring device to communicate with an external processor.

20. The noise monitoring device of claim 18 wherein said noise monitoring device is provided with an individual device identification communicator.

21. The noise monitoring device of claim 20 provided with device programming and data retrieval capability.

22. The noise monitoring device of claim 19 wherein said remote interface capability is provided by infrared communication.

23. The noise monitoring device of claim 21 wherein said noise monitoring device includes a library of pre-defined and user-defined set-up files for configuring the noise monitoring device for specific user applications.

24. The noise monitoring device of claim 21 wherein said noise monitoring device is equipped to provide information from said evaluator to a remote control processor.

25. The noise monitoring device of claim 1 wherein said evaluator determines a projected time-weighted average noise level and compares that level to a first Alert Level for the purpose issuing a noise exposure warning.

26. The noise monitoring device of claim 25 wherein said evaluator also determines a measured time-weighted average noise level and compares that level to a second Alert Level for the purpose of issuing a noise exposure warning.

27. The noise monitoring device of claim 6 wherein said Alert Levels correspond to noise exposure compliance levels.

28. The noise monitoring device of claim 27 wherein said noise exposure compliance levels correspond to regulatory standards.
